(19) United States
(12) Patent Application Publication
(10) Pub. No.: US 2008/0111181 A1
(43) Pub. Date: May 15, 2008

(54) Nonvolatile memory devices, methods of operating the same and methods of forming the same

(75) Inventors: Weon-Ho Park, Suwon-si (KR); Jeong-Uk Han, Suwon-si (KR); Yong-Tae Kim, Yongin-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/982,036

(22) Filed: Nov. 1, 2007

(30) Foreign Application Priority Data
Nov. 15, 2006 (KR) 10-2006-0112980

(51) Int. Cl. H01L 29/788; H01L 21/336

(52) U.S. Cl. 257/319; 438/264; 257/E29.3; 257/E21.422

(57) ABSTRACT

A nonvolatile memory (NVM) device includes a floating gate on a semiconductor substrate and a gate insulating layer between the semiconductor substrate and the floating gate. A tunnel insulating layer is disposed between the semiconductor substrate and the floating gate. The tunnel insulating layer is thinner than the gate insulating layer. A first inter-gate insulating layer is disposed on the floating gate, and a sensing gate is disposed on the first inter-gate insulating layer. The sensing gate covers a first portion of the floating gate. A control gate is disposed to cover a top surface and a sidewall of a second portion of the floating gate. A second inter-gate insulating layer is disposed between the control gate and the sensing gate and between the control gate and the floating gate. Operation methods and fabrication methods of the NVM device are also provided.

### CROSS-REFERENCE TO RELATED APPLICATION

This application claims priority from Korean Patent Application No. 10-2006-112980, filed Nov. 15, 2006, the disclosure of which is hereby incorporated herein by reference in its entirety.

### BACKGROUND OF THE INVENTION

1. Field of the Invention

Embodiments of the present invention relate to semiconductor devices, methods of operating the same and methods of forming the same and, more particularly, to nonvolatile memory (NVM) devices, methods of operating the same and methods of forming the same.

2. Description of the Related Art

Nonvolatile memory (NVM) devices retain their stored data even when their power supplies are turned off. Accordingly, NVM devices have been widely used in conjunction with computers, mobile telecommunication systems, memory cards, and the like. NVM devices include the following types: mask read only memory (ROM) devices, electrically programmable read only memory (EPROM) devices, electrically erasable programmable read only memory (EEPROM) devices and flash memory devices. The EEPROM device commonly includes a floating gate tunneling oxide (FLOTOX) transistor and a selection transistor.

FIG. 1 is a cross-sectional view illustrating a unit cell of a conventional NVM device.

Referring to FIG. 1, a gate insulating layer 20 is provided on a semiconductor substrate 10. A floating gate 32a, a first inter-gate insulating layer 34a and a sensing gate 36a are sequentially stacked on the gate insulating layer 20. A tunnel insulating layer 25 is interposed between the floating gate 32a and the semiconductor substrate 10. Further, a first selection gate 32b, a second inter-gate insulating layer 34b and a second selection gate 36b are sequentially stacked on the gate insulating layer 20. A floating junction region 12 is provided in the semiconductor substrate 10 below gap region between the floating gate 32a and the first selection gate 32b. A source region 15s is provided in the semiconductor substrate 10 at a position adjacent an opposite portion of the floating gate 32a opposite the floating junction region 12, and a drain region 15d is provided in the semiconductor substrate 10 at a position adjacent an opposite portion of the first selection gate 32b opposite the floating junction region 12.

The tunnel insulating layer 25, the floating gate 32a, the first inter-gate insulating layer 34a, the sensing gate 36a, the source region 15s and the floating junction region 12 constitute a FLOTOX transistor, e.g., a memory cell transistor. In addition, the gate insulating layer 20, the first selection gate 32b, the second inter-gate insulating layer 34b, the second selection gate 36b, the drain region 15d and the floating junction region 12 constitute a selection transistor. The memory transistor and selection transistor are covered with an interlayer insulating layer 40. A bit line contact plug 50 penetrates the interlayer insulating layer 40 to be in contact with the drain region 15d. A bit line 60, which is electrically connected to the bit line contact plug 50, is disposed on the interlayer insulating layer 40.

A programming operation of the EEPROM illustrated in FIG. 1 may be achieved by applying a high voltage of about 15 to 20 volts to the sensing gate 36a and the second selection gate 36b, and an erasure operation thereof may be achieved by applying a high voltage of about 15-20 volts to the drain region 15d and the second selection gate 36b.

As described above, application of a high voltage is required to program or erase the conventional EEPROM device. This introduces certain limitations in reducing the size of the memory transistor and the selection transistor and a width of an isolation layer to be formed between the unit cells of the conventional EEPROM device. In other words, increasing the integration density of the conventional EEPROM can be limited.

Further, when the programming operation is performed by a channel hot carrier injection mechanism, the gate insulating layer 20 and/or the tunnel insulating layer 25 may be easily worn out. As a result, reliability of the EEPROM, for example, an endurance characteristic can become degraded.

### SUMMARY OF THE INVENTION

Embodiments of the present invention are directed to nonvolatile memory (NVM) devices, methods of operating the same, and methods of forming the same in which endurance characteristics can be improved and integration density can be increased.

In one aspect, embodiments of the present invention are directed to a nonvolatile memory device comprising: a floating gate on a semiconductor substrate; a gate insulating layer between the semiconductor substrate and the floating gate; a tunnel insulating layer between the semiconductor substrate and the floating gate, the tunnel insulating layer having a thickness that is less than a thickness of the gate insulating layer; a first inter-gate insulating layer on the floating gate; a sensing gate on the first inter-gate insulating layer, the sensing gate covering a first portion of the floating gate; a control gate covering a top surface and a sidewall of a second portion of the floating gate; and a second inter-gate insulating layer between the control gate and the sensing gate and between the control gate and the floating gate.

In one embodiment, the tunnel insulating layer comprises a silicon oxide layer or a silicon oxynitride layer.

In another embodiment, the nonvolatile memory device further comprises a floating junction region disposed in the semiconductor substrate in contact with the tunnel insulating layer.

In another embodiment, the nonvolatile memory device further comprises: a drain region in the semiconductor substrate spaced apart from the floating junction region and adjacent to the control gate; and a source region in the semiconductor substrate spaced apart from the floating junction region, adjacent to the floating gate and opposite the drain region.

In another embodiment, programming the nonvolatile memory device comprises: applying a ground voltage to the drain region; and applying a program voltage to the sensing gate so that charge present in the floating junction region is injected into the floating gate through the tunnel insulating layer by a Fowler-Nordheim tunneling operation.

In another embodiment, erasing the nonvolatile memory device comprises: applying a ground voltage to the drain region and the sensing gate; and applying an erasure voltage to the control gate so that charge stored in the floating gate is emitted into the control gate.

In another aspect, embodiments of the present invention are directed to a method of forming a nonvolatile memory device, the method comprising: forming a gate insulating layer on a semiconductor substrate; forming a tunnel insulating layer on the semiconductor substrate by removing a portion of the gate insulating layer; forming a floating gate on the tunnel insulating layer and the gate insulating layer; forming a first inter-gate insulating layer on the floating gate; forming a sensing gate on the first inter-gate insulating layer, the sensing gate overlapping a first portion of the floating gate; forming a second inter-gate insulating layer that covers a portion of the sensing gate and a sidewall of the floating gate; and forming a control gate on the second inter-gate insulating layer, the control gate covering a top surface and a sidewall of a second portion of the floating gate.

In one embodiment, the method further comprises forming a floating junction region in the semiconductor substrate before forming of the tunnel insulating layer, wherein the floating junction region is in contact with the tunnel insulating layer.

In another embodiment, forming the tunnel insulating layer comprises: forming a photoresist pattern on the gate insulating layer; etching the gate insulating layer using the photoresist pattern as an etch mask to expose a portion of the semiconductor substrate; and forming a thermal oxide layer on the exposed semiconductor substrate by performing thermal oxide process.

In another embodiment, the method further comprises implanting impurity ions into the semiconductor substrate using the photoresist pattern as an ion implantation mask, thereby forming a floating junction region in the semiconductor substrate.

In another embodiment, the method further comprises forming a drain region in the semiconductor substrate spaced apart from the floating junction region and adjacent to the control gate and a source region in the semiconductor substrate spaced apart from the floating junction region and adjacent to the floating gate and opposite the drain region.

In another aspect, embodiments of the present invention are directed to a method of operating a nonvolatile memory device. The operation method comprises a program method and an erasure method. The program method comprises applying a first program voltage to a sensing gate formed over a semiconductor substrate. The sensing gate is disposed on a first portion of a floating gate between the sensing gate and the semiconductor substrate. A second program voltage is applied to a control gate which covers a top surface and a sidewall of a second portion of the floating gate. A ground voltage is applied to a drain region in the semiconductor substrate adjacent to the control gate so that charge present in a floating junction region formed in the semiconductor substrate under the floating gate are injected into the floating gate through a tunnel insulating layer between the floating gate and the floating junction region.

In some embodiments, the first and second program voltage may be 8 to 15 volts.

In another embodiment, the erasure method may comprise applying a ground voltage to the sensing gate and the drain region, and applying an erasure voltage to the control gate so that charge stored in the floating gate is injected into the control gate through an inter-gate insulating layer between the floating gate and the control gate.

In some embodiments, the erasure voltage may be 8 to 15 volts.

### BRIEF DESCRIPTION OF THE DRAWINGS

Embodiments of the invention can be more readily understood in further detail from the following descriptions taken in conjunction with the accompanying drawings in which:

FIG. 1 is a cross-sectional view illustrating a conventional NVM device;

FIG. 2 is a cross-sectional view illustrating an NVM device according to an embodiment of the present invention;

FIGS. 3 and 4 are circuit diagrams illustrating methods of operating an NVM device according to an embodiment of the present invention; and

FIGS. 5A to 5F are cross-sectional views illustrating a method of forming an NVM device according to an embodiment of the present invention.

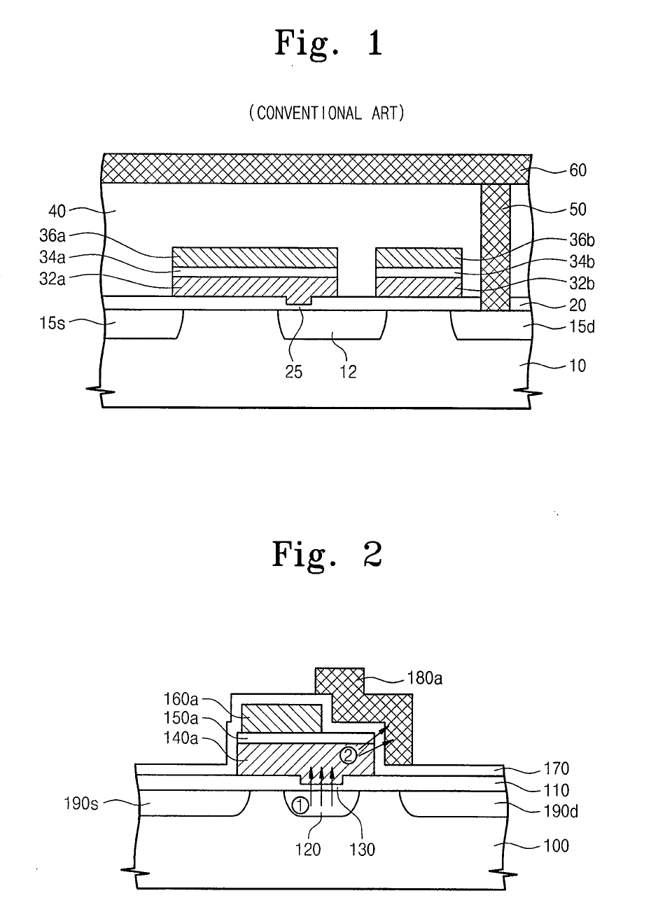

### DETAILED DESCRIPTION OF EMBODIMENTS OF THE INVENTION

Embodiments of the present invention will now be described more fully hereinafter with reference to the accompanying drawings, in which preferred embodiments of the invention are shown. This invention may, however, be embodied in different forms and should not be construed as limited to the embodiments set forth herein. Like numbers refer to like elements throughout the specification.

It will be understood that, although the terms first, second, etc. are used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “on” or “connected” or “coupled” to another element, it can be directly on or connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.). When an element is referred to herein as being “over” another element, it can be over or under the other element, and either directly coupled to the other element, or intervening elements may be present, or the elements may be spaced apart by a void or gap.

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

(Structure of NVM Device)

FIG. 2 is a cross-sectional view illustrating a memory cell unit of an NVM device according to an embodiment of the present invention.

Referring to FIG. 2, a floating gate 140a is disposed on a semiconductor substrate 100. The floating gate 140a may comprise a polysilicon layer. A gate insulating layer 110 is disposed between the floating gate 140a and the semiconductor substrate 100. The gate insulating layer may comprise a silicon oxide layer. A tunnel insulating layer 130 is disposed between the floating gate 140a and the semiconductor substrate 100. The tunnel insulating layer 130 may comprise a portion of a silicon oxide layer or a silicon oxynitride layer having a thickness that is less than remaining portions of the gate insulating layer 110. A floating junction region 120 is provided in the semiconductor-substrate 100 below and in contact with the tunnel insulating layer 130. The floating junction region 120 can comprise, for example, an impurity region which is heavily doped with N-type impurities. The N-type impurities can comprise, in various embodiments, phosphorous ions or arsenic ions, for example.

A first inter-gate insulating layer 150a is disposed on the floating gate 140a. The first inter-gate insulating layer 150a may comprise a silicon oxide layer or an oxide-nitride-oxide (ONO) layer. A sensing gate 160a is disposed on the first inter-gate insulating layer 150a. The sensing gate 160a can be configured to overlap with a first portion of the floating gate 140a. The sensing gate 160a can comprise at least one of a polysilicon layer and a metal silicide layer. A control gate 180a is disposed to cover a top surface and a sidewall of a second portion of the floating gate 140a. The control gate 180a may comprise at least one of a polysilicon layer and a metal silicide layer. A second inter-gate insulating layer 170 is disposed between the sensing gate 160a and the control gate 180a as well as between the floating gate 140a and the control gate 180a. The second inter-gate insulating layer 170 can comprise, for example, a silicon oxide layer.

A drain region 190d is provided in the semiconductor substrate 100 adjacent to the control gate 180a, and a source region 190s is provided in the semiconductor substrate 100 at a position adjacent to the floating gate 140a and opposite the drain region 190d. The source region 190s and the drain region 190d can comprise impurity regions that are heavily doped with N-type impurities such as arsenic ions. In a programming operation, carriers such as electrons present in the floating junction region 120 may be injected into the floating gate 140a through the tunnel insulating layer 130 as indicated by the arrows \textcircled{1}.

Meanwhile, in an erasure operation, carriers such as the electrons stored in the floating gate 140a may be injected into the control gate 180a through the second inter-gate insulating layer 170. In particular, during an erasure operation, most of the electrons present in the floating gate 140a can be ejected from the tip at the top corner of the floating gate 140a which is covered by the control gate 180a, as indicated by the arrows \textcircled{2}. This is because the electric field between the floating gate 140a and the control gate 180a is concentrated at the tip of the floating gate 140a during the erasure operation.

(Methods of Operating NVM Device)

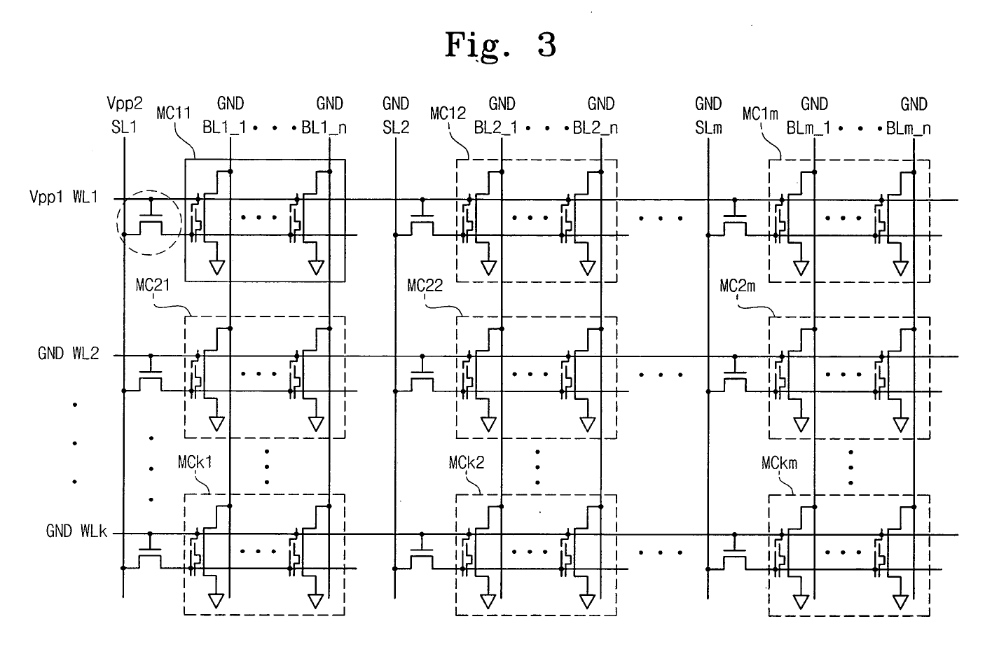

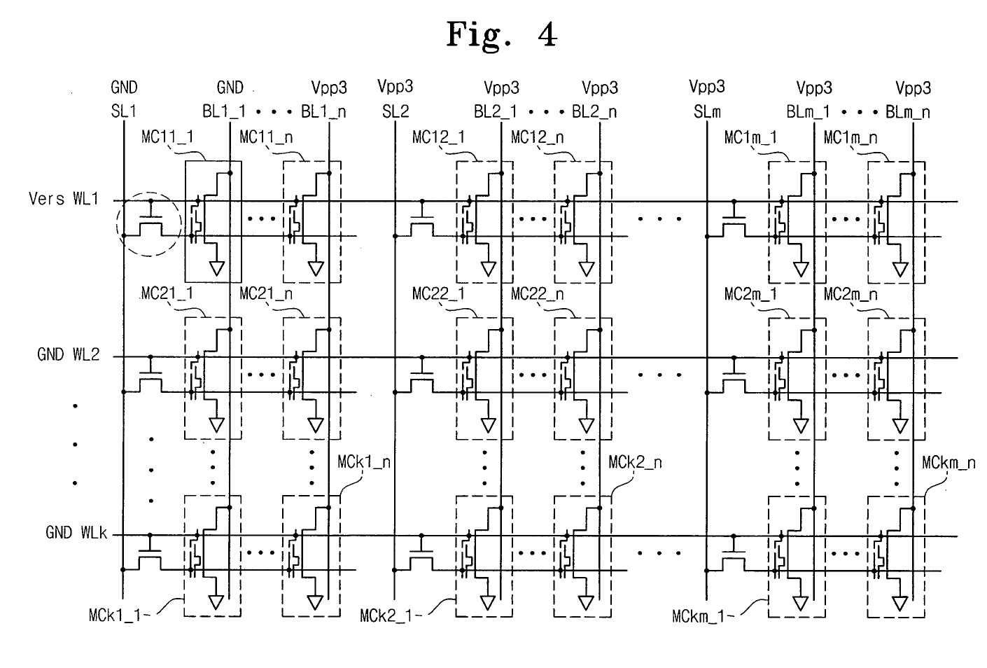

FIGS. 3 and 4 are circuit diagrams illustrating methods of operating an NVM device employing the memory cell unit shown in FIG. 2.

Referring to FIGS. 3 and 4, the NVM device comprises a plurality of memory cell units MC11_1˜MCkm_n which are two-dimensionally arrayed along rows and columns. A plurality of word lines WL1˜WLk extend in a direction to be parallel with the rows, and a plurality of bit lines BL1_1˜BLm_n extend in a direction to be parallel with the columns and intersect the word lines WL1˜WLk. Therefore, the memory cell units MC11_1˜MCkm_n may be located at intersections of the word lines WL1˜WLk and the bit lines BL1_1˜BLm_n, respectively. The bit lines may be divided into a first block of bit lines BL1_1˜BL1_n to an m^{th} block of bit lines BLm_1˜BLm_n, and the memory cell units may also be divided into a first block of memory cell units MC11_1˜MCk1_n to an m^{th} block of memory cell units MC1m_1˜MCkm_n. Each of the word lines WL1˜WLk extends to run across the m-number of cell blocks.

Each of the memory cell units is electrically connected to one of the word lines WL1˜WLk and one of the bit lines BLm_1˜BLm_n. In more detail, the drain region (190d of FIG. 2) of each memory cell unit is electrically connected to one of the bit lines BLm_1˜BLm_n, and the control gate (180a of FIG. 2) of each memory cell unit is electrically connected to one of the word lines WL1˜WLk.

In addition, first to m^{th} sensing lines SL1˜SLm are disposed in the first to m^{th} cell blocks, respectively. The sensing gates (160a of FIG. 2) of the memory cell units, which are arrayed along the same row in each cell block, are electrically connected to one of the first to m^{th} sensing lines SL1˜SLm through a sensing transistor (shown in a dotted circle). A gate electrode of the sensing transistor is electrically connected to one of the word lines WL1˜WLk.

A method of selectively programming certain memory cell units will be described with reference to FIG. 3.

Referring to FIG. 3, first and second program voltages Vpp1 and Vpp2 may be respectively applied to the first word line WL1 and the first sensing line SL1 in order to selectively program the memory cell units MC11 (shown in a solid rectangle) which are electrically connected to the first word line WL1 in the first cell block. Further, a ground voltage GND may be applied to all the bit lines BL1_1˜BLm_n, the second to m^{th} sensing lines SL2˜SLm, and the second to k^{th} word lines WL2˜WLk. The first program voltage Vpp1 and the second program voltage Vpp2 may be about 8 to 15 volts. In this case, the memory cell units MC12˜MCkm (shown in dotted rectangles), which are connected to the second to k^{th} word lines WL2˜WLk and the second to m^{th} sensing lines SL2˜SLm, are not selected.

Under the bias condition described above, the ground voltage GND is applied to the drain regions 190d of the selected memory cell units MC11, and the second program voltage Vpp2 is applied to the sensing gates 160a of the selected memory cell units MC11. In addition, the first program voltage Vpp1 is applied to the control gates 180a of the selected memory cell units MC11, thereby forming inversion channels between the floating junction regions 120 and the drain regions 190d. Thus, the ground voltage GND may be applied to the floating junction regions 120 through the inversion channels. As a result, carriers such as electrons present in the floating junction regions 120 are injected into the floating gates 140a through the tunnel insulating layers (130 of FIG. 2) by the Fowler-Nordheim (F-N) tunneling mechanism (refer to the arrows \textcircled{1} of FIG. 2).

In a case where the program operation is achieved by the F-N tunneling mechanism, the programmed memory cell units may exhibit more uniform threshold voltages and more improved endurance characteristics as compared to the case where the memory cell unit is programmed by a channel hot carrier injection mechanism. Moreover, a high voltage level such as the first or second program voltage Vpp1 or Vpp2 is not applied to the drain regions 190d during the program operation. Accordingly, the memory cell units may be more readily scaled down to increase the integration density of the NVM device. Once the memory cell units MC11 are programmed, threshold voltages of the programmed memory cell units MC11 are increased. Thus, the programmed memory cell units MC11 can be turned off during a read operation.

A method of selectively erasing a single memory cell unit will now be described with reference to FIG. 4.

Referring FIG. 4, in order to selectively erase the memory cell unit MC11_1 (shown in a solid rectangle) which is electrically connected to the first WL1 and the first bit line BL1_1 in the first cell block, an erasure voltage Vₑᵣₛ may be applied to the first word line WL1 and a ground voltage GND may be applied to the first bit line BL1_1 in the first cell block and first sensing line SL1. Further, the ground voltage GND may be applied to the second to k^{th} word lines WL2˜WLk and an erasure inhibition voltage Vpp3 may be applied to the bit lines BL1_2˜BLm_n and the second to m^{th} sensing lines SL2˜SLm. In one example, the erasure voltage Vₑᵣₛ may be about 8 to 15 volts and the erasure inhibition voltage Vpp3 may be about 2 to 7 volts. In this case, the memory cell units MC11_2˜MCkm_n (shown in dotted rectangles), which are connected to the second to k^{th} word lines WL2˜WLm and the bit lines BL1_2˜BLm_n, may not be selected.

Under the bias condition described above, the erasure voltage Vₑᵣₛ is applied to the control gate 180a of the selected memory cell unit MC11_1 and the ground voltage GND is applied to the drain region 190d and the sensing gate 160a of the selected memory cell unit MC11_1. Thus, the ground voltage GND may be applied to the floating junction region 120 of the selected memory cell unit MC11_1 through the drain region 190d and an inversion channel is formed under the control gate 180a. In this case, the floating gate 140a of the selected memory cell unit MC11_1 may have substantially the ground voltage GND since the floating gate 140a is disposed between the grounded sensing gate 160a and the grounded floating junction region 120. As a result, carriers such as electrons present in the floating gate 140a may be injected into the control gate 180a through the inter-gate insulating layers 150a and 170 which are disposed between the floating gate 140a and the control gate 180a. Most of the electrons present in the floating gate 140a may be ejected from the tip of the floating gate 140a that is covered with the control gate 180a. (for example, refer to the arrows \textcircled{2} of FIG. 2) This is due to the concentration of the electric field at the tip of the floating gate 140a.

According to the erasure operation described above, any high voltage such as the erasure voltage Vₑᵣₛ is not applied to the drain regions 190d during the erasure operation. Thus, the memory cell units may be more readily scaled down to increase the integration density of the NVM device. Once the memory cell unit MC11_1 is erased, a threshold voltage of the erased memory cell units MC11_1 is decreased. Thus, the erased memory cell unit MC11_1 is turned on during a read operation.

(Methods of Forming an NVM Device)

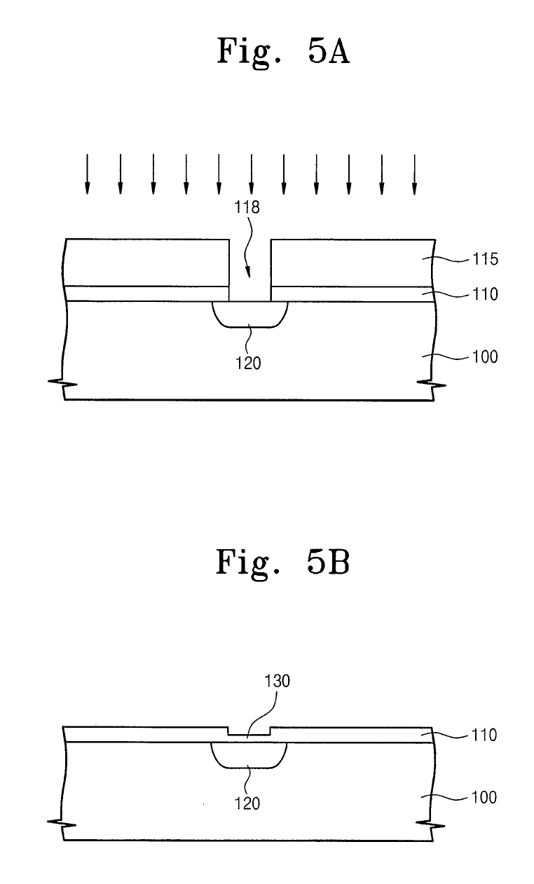

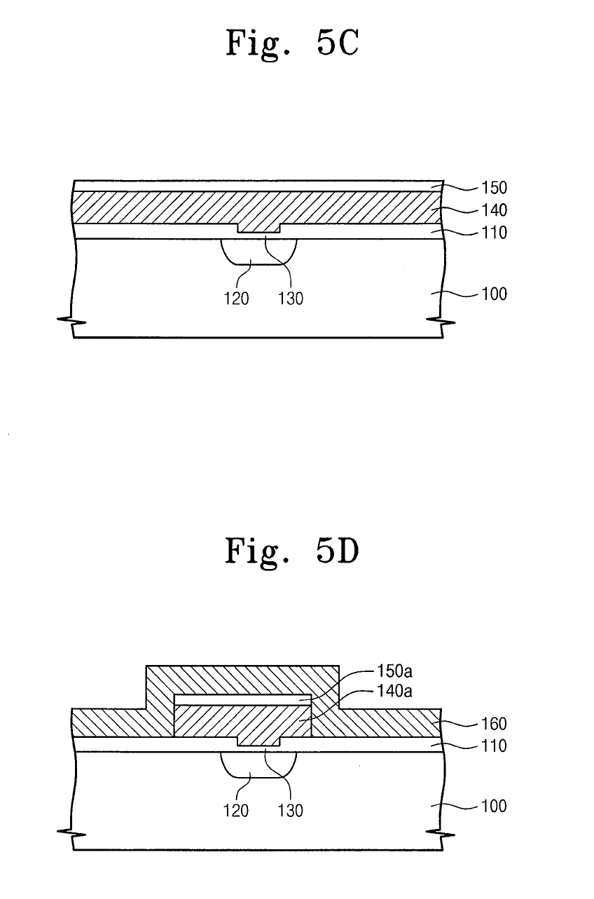

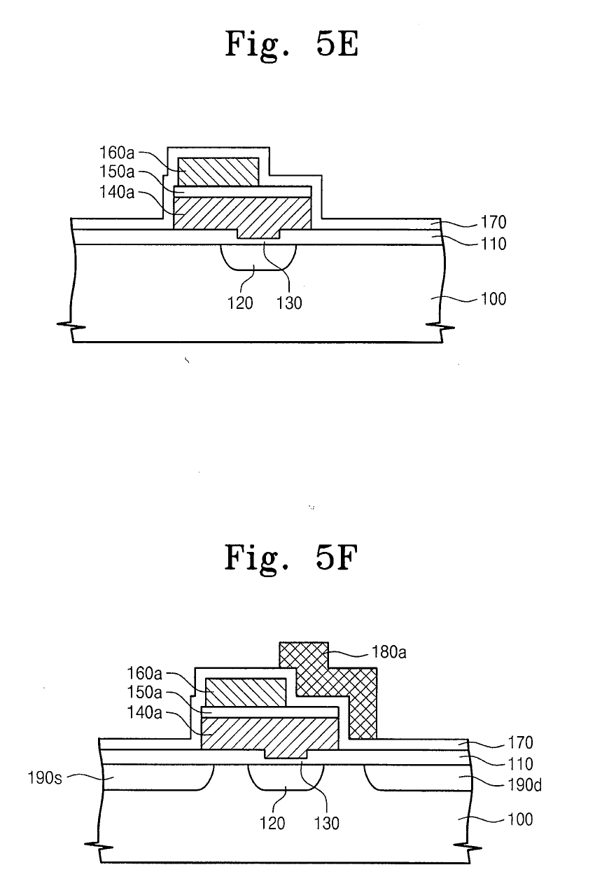

FIGS. 5A to 5F are cross-sectional views illustrating methods of forming an NVM device according to an embodiment of the present invention.

Referring to FIG. 5A, a gate insulating layer 110 is formed on a semiconductor substrate 100. The gate insulating layer 110 may be formed of a thermal oxide layer. A photoresist pattern 115 is formed on the gate insulating layer 110. The photoresist pattern 115 is formed to have an opening 118 that exposes a portion of the gate insulating layer 110. The gate insulating layer 110 is etched using the photoresist pattern 115 as an etch mask, thereby exposing a portion of the semiconductor substrate 100. N-type impurity ions, for example, phosphorous ions or arsenic ions are implanted with a high dose into the semiconductor substrate using the photoresist pattern 115 as an ion implantation mask, thereby forming a floating junction region 120 in the semiconductor substrate 100. The photoresist pattern 115 is then removed.

Referring to FIG. 5B, a tunnel insulating layer 130 is formed on the floating junction region 120. The tunnel insulating layer 130 may be formed of a thermal oxide layer. The tunnel insulating layer 130 may be formed to have a thickness that is less than that of the gate insulating layer 110.

Referring to FIG. 5C, a first conductive layer 140 is formed on the gate insulating layer 110 and the tunnel insulating layer 130. The first conductive layer 140 may be formed of a polysilicon layer using a chemical vapor deposition (CVD) technique. An insulating layer 150 is formed on the first conductive layer 140. The insulating layer 150 may be formed, by way of example, of a silicon oxide layer or an oxide-nitride-oxide (ONO) layer using a CVD technique.

Referring to FIG. 5D, a photoresist pattern (not shown) is formed on the insulating layer 150. The insulating layer 150 and the first conductive layer 140 are etched using the photoresist pattern as an etch mask, thereby forming a floating gate 140a and a first inter-gate insulating layer 150a which are sequentially stacked. The floating gate 140a is formed to cover the tunnel insulating layer 130. The photoresist pattern is then removed. A second conductive layer 160 is formed on the first inter-gate insulating layer 150a, the floating gate 140a and the gate insulating layer 110. The second conductive layer 160 is formed to include at least one of a polysilicon layer and a metal silicide layer.

Referring to FIG. 5E, the second conductive layer 160 is patterned to form a sensing gate 160a which covers a first portion of the floating gate 140a. A second inter-gate insulating layer 170 is formed on the substrate having the sensing gate 160a.

Referring to FIG. 5F, a third conductive layer is formed on the second inter-gate insulating layer 170. The third conductive layer can be formed, for example, to include at least one of a polysilicon layer and a metal silicide layer. The third conductive layer is patterned to form a control gate 180a which covers at least a portion of a top surface and a sidewall of a second portion of the floating gate 140a. In the present embodiment, the control gate 180a may be formed to cover at least an upper tip of the second portion of the floating gate 140a. N-type impurity ions, for example, arsenic ions, may be implanted into the semiconductor substrate using the floating gate 140a, the sensing gate 160a and the control gate 180a as ion implantation masks. As a result, a drain region 190d may be formed in the semiconductor substrate 100 adjacent to the control gate 180a, and a source region 190s may be formed in the semiconductor substrate 100 adjacent to the floating gate 140a and opposite the drain region 190d.

Though not shown in FIG. 5F, an interlayer insulating layer may be formed on the substrate having the source/drain regions 190s and 190d, and a bit line may be formed on the interlayer insulating layer. The bit line may be electrically connected to the drain region 190d through a bit line contact plug that penetrates the interlayer insulating layer.

According to the embodiments described above, an NVM cell having a tunnel insulating layer is programmed by an F-N tunneling mechanism. Further, any high voltage is not applied to a drain region of the NVM cell during a program operation and an erasure operation. Thus, the reliability of the tunnel insulating layer can be improved to enhance endurance characteristics of the NVM cell, and the NVM cell may be more readily scaled down to increase the integration density of the NVM device having the NVM cell.

While the present invention has been particularly shown and described with reference to embodiments thereof, it will be understood by those skilled in the art that various changes in form and details may be made herein without departing from the spirit and scope of the present invention as defined by the following claims.

What is claimed is:

1. A nonvolatile memory device comprising:
a floating gate on a semiconductor substrate;
a gate insulating layer between the semiconductor substrate and the floating gate;
a tunnel insulating layer between the semiconductor substrate and the floating gate, the tunnel insulating layer having a thickness that is less than a thickness of the gate insulating layer;
a first inter-gate insulating layer on the floating gate;
a sensing gate on the first inter-gate insulating layer, the sensing gate covering a first portion of the floating gate;
a control gate covering a top surface and a sidewall of a second portion of the floating gate; and
a second inter-gate insulating layer between the control gate and the sensing gate and between the control gate and the floating gate.

2. The nonvolatile memory device of claim 1, wherein the tunnel insulating layer comprises a silicon oxide layer or a silicon oxynitride layer.

3. The nonvolatile memory device of claim 1, further comprising a floating junction region disposed in the semiconductor substrate in contact with the tunnel insulating layer.

4. The nonvolatile memory device of claim 3, further comprising:
a drain region in the semiconductor substrate spaced apart from the floating junction region and adjacent to the control gate; and
a source region in the semiconductor substrate spaced apart from the floating junction region, adjacent to the floating gate and opposite the drain region.

5. The nonvolatile memory device of claim 4, wherein programming the nonvolatile memory device comprises:
applying a ground voltage to the drain region; and
applying a program voltage to the sensing gate so that charge present in the floating junction region is injected into the floating gate through the tunnel insulating layer by a Fowler-Nordheim tunneling operation.

6. The nonvolatile memory device of claim 4, wherein erasing the nonvolatile memory device comprises:
applying a ground voltage to the drain region and the sensing gate; and
applying an erasure voltage to the control gate so that charge stored in the floating gate is emitted into the control gate.

7. A method of forming a nonvolatile memory device, comprising:
forming a gate insulating layer on a semiconductor substrate;
forming a tunnel insulating layer on the semiconductor substrate by removing a portion of the gate insulating layer;
forming a floating gate on the tunnel insulating layer and the gate insulating layer;
forming a first inter-gate insulating layer on the floating gate;
forming a sensing gate on the first inter-gate insulating layer, the sensing gate overlapping a first portion of the floating gate;
forming a second inter-gate insulating layer that covers a portion of the sensing gate and a sidewall of the floating gate; and
forming a control gate on the second inter-gate insulating layer, the control gate covering a top surface and a sidewall of a second portion of the floating gate.

8. The method of claim 7, further comprising forming a floating junction region in the semiconductor substrate before forming of the tunnel insulating layer, wherein the floating junction region is in contact with the tunnel insulating layer.

9. The method of claim 7, wherein forming the tunnel insulating layer comprises:
forming a photoresist pattern on the gate insulating layer;
etching the gate insulating layer using the photoresist pattern as an etch mask to expose a portion of the semiconductor substrate; and
forming a thermal oxide layer on the exposed semiconductor substrate by performing thermal oxide process.

10. The method of claim 9, further comprising implanting impurity ions into the semiconductor substrate using the photoresist pattern as an ion implantation mask, thereby forming a floating junction region in the semiconductor substrate.

11. The method of claim 7, further comprising forming a drain region in the semiconductor substrate spaced apart from the floating junction region and adjacent to the control gate and a source region in the semiconductor substrate spaced apart from the floating junction region and adjacent to the floating gate and opposite the drain region.
